(19) United States
(12) Patent Application Publication
(10) Pub. No.: US 2011/0228615 A1
(43) Pub. Date: Sep. 22, 2011

(54) SEMICONDUCTOR MEMORY DEVICE

(76) Inventor: Hitoshi SHIGA, Yokohama-shi (JP)

(21) Appl. No.: 13/033,259

(22) Filed: Feb. 23, 2011

(30) Foreign Application Priority Data
Mar. 19, 2010 (JP) 2010-064741

(51) Int. Cl. G11C 7/10

(52) U.S. Cl. 365/189.05

(57) ABSTRACT

According to one embodiment, a semiconductor memory device includes unit structures. Each unit structure includes bit lines, memory cells, sense amplifiers, a first data line, a computing circuit, a second data line, and data latches. The bit lines are connected to memory cells. The sense amplifiers are connected to respective bit lines adjacent to each other. The first data line is commonly connected to the sense amplifiers. The computing circuit is connected to the first data line. The second data line is connected to the computing circuit. The data latches are connected to the second data line. The unit structures are independent from one another. At least one of the unit structures is a spare unit structure. One of the unit structures is configured to be replaceable with the spare unit structure.

### CROSS-REFERENCE TO RELATED APPLICATIONS

This application is based upon and claims the benefit of priority from Japanese Patent Application No. 2010-064741, filed Mar. 19, 2010; the entire contents of which are incorporated herein by reference.

### FIELD

Embodiments described herein relate generally to semiconductor memory devices, and more particularly to a redundancy system of a semiconductor memory device.

### BACKGROUND

A redundancy system for replacing defective components is known in semiconductor memory devices. In most cases, replacement of defective components in a redundancy system is performed with a predetermined number of adjacent bit lines used as a unit. The redundancy system is designed not only to recover defective memory cells or bit lines but also targets peripheral circuits other than the memory cell array, for example. Such peripheral circuits include a data bus, a computing circuit, a latch, and the like, provided between a bit line and a bus connected to an external connection terminal, for example.

Jpn. Pat. Appln. KOKAI Publication No. 2009-158061 discloses a sense amplifier connected to a data storage circuit in a bit-line control circuit, a computing circuit connected to the sense amplifier, and a data control unit connected to the computing circuit.

Jpn. Pat. Appln. KOKAI Publication No. 2009-54246 relates to a specific verification operation in a semiconductor memory device including memory cells each capable of storing more than one bits. Jpn. Pat. Appln. KOKAI Publication No. 2009-54246 discloses that a sense amplifier connected to a bit line and a set of computing units and first to third latch circuits connected to the sense amplifier are provided for each bit line.

Depending on the configuration between bit lines and buses connected to external connection terminals, the unit that can be replaced differs. This replacement unit causes difference in efficiency of replacement or capacity that can be reserved. Accordingly, a semiconductor memory device is desired that is capable of replacing defective elements efficiently.

### BRIEF DESCRIPTION OF THE DRAWINGS

FIG. 1 illustrates a reference example of a portion of a semiconductor memory device;

FIG. 2 illustrates the state in which a column COL0 of FIG. 1 is selected;

FIG. 3 illustrates the state in which a column COL2 of FIG. 1 is selected;

FIG. 4 is a block diagram of a semiconductor memory device according to a first embodiment;

FIG. 5 is a circuit diagram of a portion of a memory cell array;

FIG. 6 is a cross-sectional view of a portion of the memory cell array;

FIG. 7 is a block diagram illustrating a data latch and a sense amplifier circuit of the first embodiment;

FIG. 8 is a block diagram illustrating a unit structure of the first embodiment;

FIG. 9 is a block diagram illustrating a circuit relating to a redundancy circuit of the first embodiment;

FIG. 10 illustrates a state of the circuit relating to the redundancy circuit during operation;

FIG. 11 illustrates the state following FIG. 10;

FIG. 12 illustrates the state following FIG. 11;

FIG. 13 is a block diagram of a semiconductor memory device according to a third embodiment;

FIG. 14 is a block diagram illustrating a data latch and a sense amplifier circuit of a second embodiment; and

FIG. 15 is a block diagram illustrating a circuit relating to a redundancy circuit of the second embodiment.

### DETAILED DESCRIPTION

In general, according to one embodiment, a semiconductor memory device includes unit structures. Each unit structure includes bit lines, memory cells, sense amplifiers, a first data line, a computing circuit, a second data line, and data latches. The bit lines are connected to memory cells. The sense amplifiers are connected to respective bit lines adjacent to each other. The first data line is commonly connected to the sense amplifiers. The computing circuit is connected to the first data line. The second data line is connected to the computing circuit. The data latches are connected to the second data line. The unit structures are independent from one another. At least one of the unit structures is a spare unit structure. One of the unit structures is configured to be replaceable with the spare unit structure.

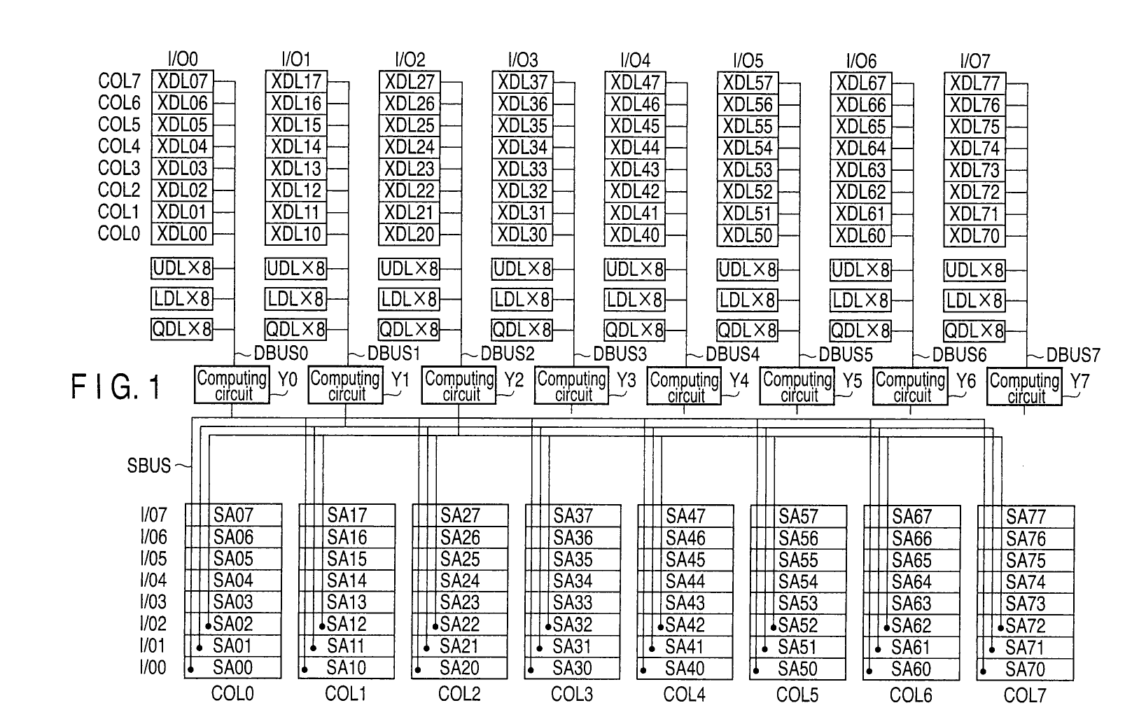

Prior to description of the embodiments, reference examples will be described with reference to FIGS. 1-3. FIG. 1 schematically shows a portion of a semiconductor memory device that uses eight bit lines as one column. A column COL0 is formed of eight adjacent bit lines. Further, columns COL1-COL7 are formed of each set of other eight adjacent bit lines.

Eight sense amplifiers SA00-SA07 are provided for column COL0. Each of the sense amplifiers SA00-SA07 is connected to a corresponding one of the eight bit lines of the column COL0, and amplifies data on the corresponding bit line. Similarly, eight sense amplifiers SAm0-SAm7 are provided for the column COLm (m being a positive integer equal to or greater than 0), and each of the sense amplifiers SAm0-SAm7 is connected to a corresponding bit line and sense-amplifies data on the corresponding bit line.

Each of the sense amplifiers SAm0 of the columns COL0-COL7 is connected to one terminal of a computing circuit Y0 via a data bus SBUS0. The computing circuit Y0 outputs a processed signal from one of the eight sense amplifiers SAm0 via the other terminal of the computing circuit Y0. Similarly, each of the sense amplifiers SAm1-SAm7 of the columns COL0-COL7 is connected to a corresponding one of the computing circuits Y1-Y7.

The other end of the computing circuit Y0 is connected to eight data latches XDL00-XDL07 via a data bus. The data latches XDL00-XDL07 latch data for the I/O0 of the columns COL0-COL7, respectively. The computing circuit Y0 supplies a signal from the other end of the computing circuit Y0 to one of the data latches XDL00-XDL07 via the data bus DBUS0, according to which of the columns COL0-COL7 is selected. More specifically, when the column COL0 is selected, the computing circuit Y0 connects its one end to a sense amplifier SA00, and the other end to a data latch XDL00 of the I/O0. Similarly, the other ends of the computing circuits Y1-Y7 are connected to a set of XDL1p, XDL2p, XDL3p, XDL4p, XDL5p, XDL6p, and XDL7p (p being an integer equal to or greater than 0 and equal to or smaller than 7), respectively, via the data buses DBUS 1-7.

The data latches XDL00-XDL07 are connected to a data bus for the I/O0 via the respective switching circuits (not shown). Similarly, data latches XDL1p-XDL7p are connected to data buses DQBUS1-DQBUS7 for the I/O1-I/O7 via the respective switching circuits (not shown).

The same components as those of FIG. 1 are provided for columns COL8-COL15, columns COL16-31, and the like.

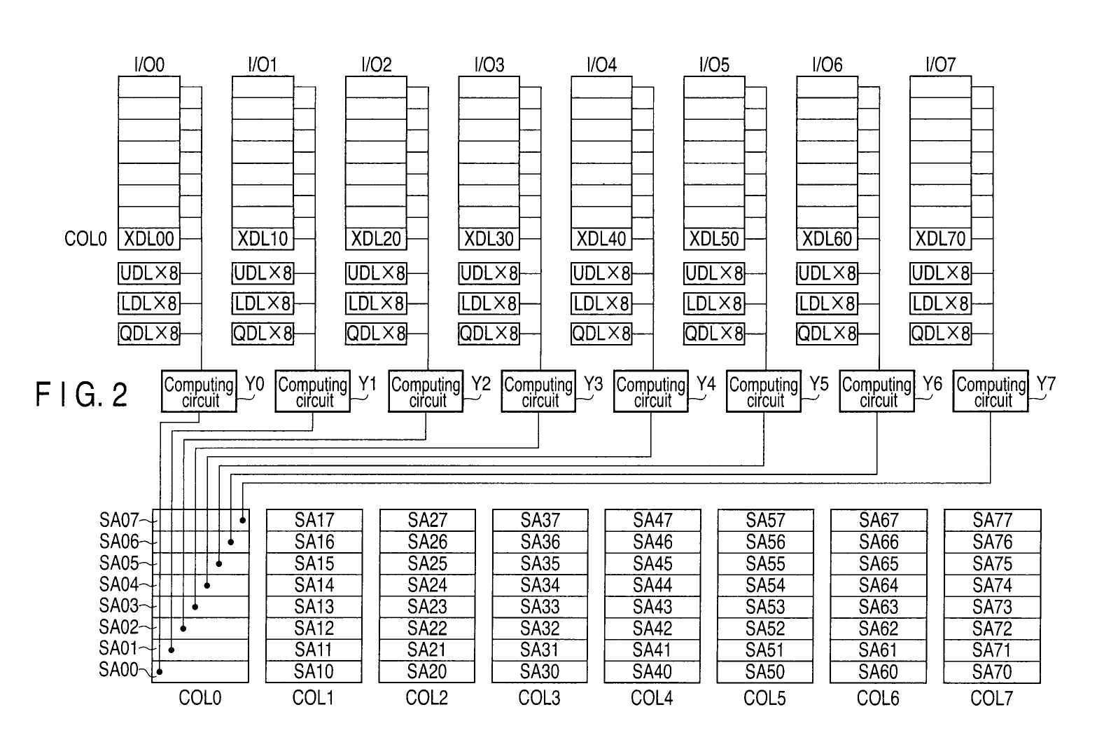

FIG. 2 illustrates connection in the FIG. 1 configuration where the column COL0 is selected, that is, where data is input/output to/from the memory cell array on bit lines belonging to the column COL0. As shown in FIG. 2, the sense amplifiers SA00-SA07 of the column COL0 are connected to XDL00, XDL10, XDL20, XDL30, XDL40, XDL50, XDL60, and XDL70 via the computing circuits Y0-Y7, respectively. Data from the sense amplifiers SA00-SA07 is then supplied to XDL00, XDL10, XDL20, XDL30, XDL40, XDL50, XDL60, and XDL70 via the computing circuits Y0-Y7, respectively. Alternatively, data held in XDL00, XDL10, XDL20, XDL30, XDL40, XDL50, XDL60, and XDL70 is supplied to the sense amplifiers SA00-SA07 via the computing circuits Y0-Y7, respectively.

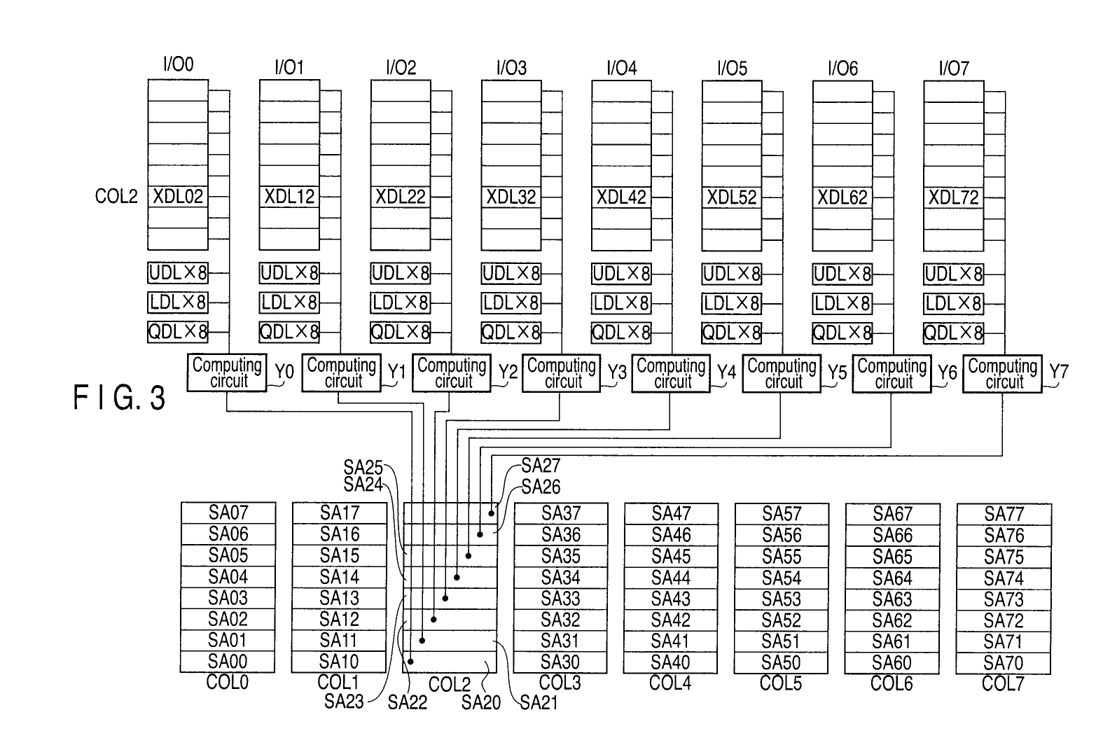

FIG. 3 illustrates connection in the FIG. 1 configuration where the column COL2 is selected. As shown in FIG. 3, the sense amplifiers SA20-SA27 of the column COL2 are connected to XDL02, XDL12, XDL22, XDL32, XDL42, XDL52, XDL62, and XDL72 via the computing circuits Y0-Y7, respectively. In order to transfer data of the columns COL0-COL7, the above-described operation for one column is repeated over time for all the columns.

Thus, the eight sense amplifiers belonging to one column is connected to the eight data latches XDL belonging to the same row of I/O0-I/O7 via the computing circuits Y0-Y7, respectively. Accordingly, in order to transfer data of one of the columns COL0-COL7, components forming one set for eight columns (that is, all the components included in the unit structure of FIG. 1) will be required. That is, whenever one column is selected, the computing circuits Y0-Y7, the data buses DBUS0-DBUS7, and the data latches XDL0p-XDL7p will be required.

Providing a redundancy mechanism with such configuration will use the following technique. That is, for defects in any of the bit lines and the sense amplifiers SA, replacement by unit of a column is possible because the bit lines and the sense amplifiers are separate column-to-column basis. On the other hand, for defects in, for example, any of the data buses SBUS, the computing circuits Y0-Y7, and the data buses DBUS0-DBUS7, the replacement unit will be all the components in FIG. 1. This is because the computing circuits Y0-Y7, the data buses DBUS0-DBUS7, and the data latches XDL0p-XDL7p are shared by the columns COL0-COL7. Accordingly, when a defect occurs in only any of the data buses SBS, the computing circuits Y0-Y7, and the data buses DBUS0-DBUS7, all the components for eight columns shown in FIG. 1 need to be replaced. With such a large replacement unit, a large capacity of the spare components is consumed by only one defective component, which will decrease efficiency in replacement. It is thereby necessary to prepare a number of spare components to secure necessary replacement capacity.

Hereinafter, embodiments configured based on the above-described knowledge will be described in detail with reference to the accompanying drawings. In the descriptions that follow, components having approximately the same functions and configurations will be denoted by the same reference numerals, and repeated description will be provided only when necessary. Note that the drawings are schematic. Further, the embodiments that will be described below only illustrates devices and methods for embodying the technical idea of the present invention, which is not intended to specify the material, shape, configuration, arrangement, and the like of the structural elements as those that will be described below. A variety of modifications may be added to the technical idea of the present invention within the scope of the claims.

Each functional block may be implemented as hardware, computer software, or combination of the both. In order to clearly illustrate this interchangeability of hardware and software, descriptions will be made in terms of their functionality in general. Whether such functionality is implemented as hardware or software depends on the particular application and design constraints imposed on the overall system. Those of skilled in the art may implement the functionality in varying ways for each particular application, but any implementation approach is included in the scope of the present invention.

### First Embodiment

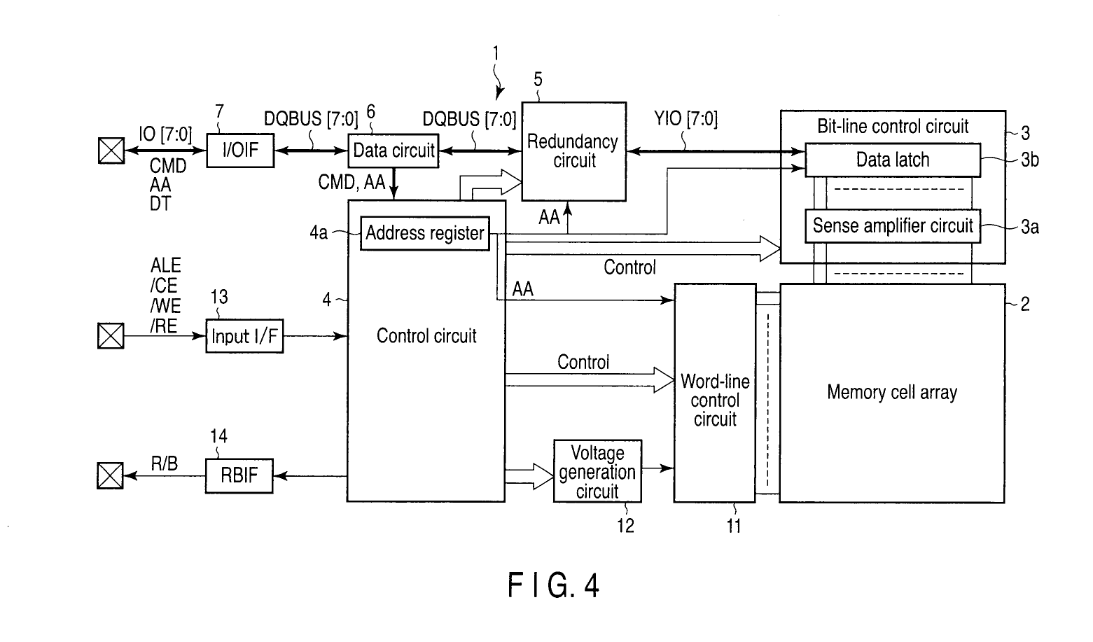

FIG. 4 is a block diagram schematically illustrating a semiconductor memory device according to a first embodiment. As shown in FIG. 4, a semiconductor memory device (or, flash memory) 1 includes a memory cell array 2. The memory cell array 2 includes bit lines, word lines, and a common source line. In the memory cell array 2, electrically programmable memory cells, such as electrically erasable programmable read only memory (EEPROM) cells, are arranged in a matrix.

A bit-line control circuit 3 is connected to the memory cell array 2. The bit-line control circuit 3 reads data in the memory cells in the memory cell array 2 via bit lines, determines the state of the memory cells via the bit lines, and writes data into the memory cells via the bit lines by applying a write (or, program) voltage to the memory cells. The bit-line control circuit 3 is controlled by a control circuit 4. The bit-line control circuit 3 includes a sense amplifier circuit 3a, and data latches 3b. The sense amplifier circuit 3a amplifies potentials on the bit lines. The data latches 3b temporarily hold data to/from the memory cell array.

The data latches 3b are connected to a redundancy circuit 5 via a data bus YIO. The data bus YIO has an eight-bit width and therefore includes eight data lines YIO0-YIO7. The redundancy circuit 5 is connected to the data circuit (or, data buffer) 6 via a data bus DQBUS. The data bus DQBUS has an eight-bit width, and therefore includes eight data lines DQBUS0-DQBUS7.

The data circuit 6 is connected to data input/output terminals via another data bus DQBUS and an I/O interface 7. A command CMD of many types, address AA, and data DT are externally supplied to the data input/output terminals. Of these, the command CMD and the address AA are supplied to the control circuit 4. The address AA and the data DT are also supplied to the redundancy circuit 5. Similarly, data read to the data latches 3b via the sense amplifier circuit 3a from the memory cell is supplied to the redundancy circuit 5, and then output from the input/output terminals.

The following descriptions are based on the example in which eight-bit data is input/output from/to the semiconductor memory device 1. However, this is not essential, and the embodiments may apply to data of more or less than eight bits using the same principle as that of the example of the eight bits.

A word-line control circuit 11 is connected to the memory cell array 2. The word-line control circuit 11 receives a voltage necessary for reading, writing, or erasure data from a voltage generation circuit 12. The word-line control circuit 11 selects a predetermined word line in the memory cell array 1 according to the control by the control circuit 4, and applies a selected voltage from the voltage generation circuit 12 to the selected word line. The voltage generation circuit 12 applies a necessary voltage to the word-line control circuit 11 in data writing, reading, erasure, or the like, according to the control by the control circuit 4.

The control circuit 4 is connected to control signal input terminals via an input interface 13. The control circuit 4 receives control signals such as Address Latch Enable (ALE), Command Latch Enable (/CLE), Write Enable (/WE), and Read Enable (RE). The control circuit 4 follow these control signals, the command CMD, and the address AA to control the bit-line control circuit 3, the redundancy circuit 5, the word-line control circuit 11, and the voltage generation circuit 12.

The control circuit 4 includes an address register 4a. The address register 4a receives an address AA via the data bus of eight-bit width from the data circuit 6. The address register 4 supplies the address AA to the redundancy circuit 5, the word-line control circuit 11, and the data latch 3b.

The control circuit 4 also outputs a Ready/Busy signal R/B via a ready/busy interface 14.

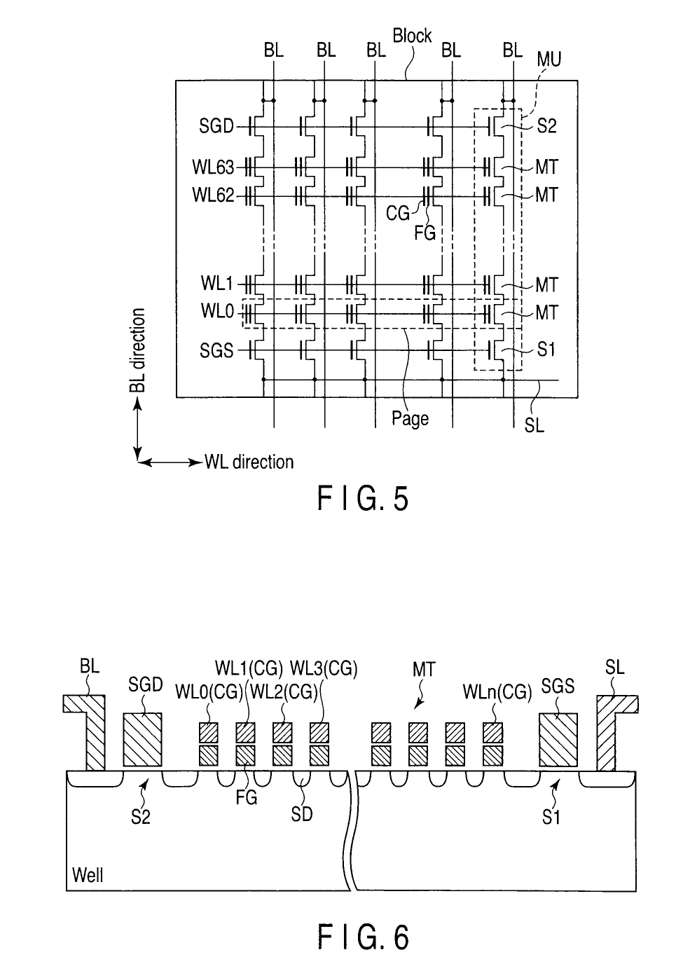

The configuration of the memory cell array 2 will now be described with reference to FIGS. 5 and 6. The memory cell array 2 includes blocks. FIG. 5 is a circuit diagram of a portion (or, one block) of the memory cell array. FIG. 6 is a cross-sectional view of a portion (or, one block) of the memory cell array.

As shown in FIGS. 5 and 6, a block includes sets of memory cell (or, memory cell units) MU arranged along the word-line direction (i.e., WL direction). The memory cell set MU is formed of a NAND string and select transistors S1, S2. The NAND string includes a predetermined number of (64, for example) memory cell transistors MT whose current paths (i.e., sources/drains SDs) are connected in series. The select transistors S1, S2 are connected to both ends of the NAND string. The other end of the current path of the select transistor S2 is connected to one bit line BL, and the other end of the current path of the select transistor S1 is connected to the source line SL. The memory cell transistors MT in the block are collectively erased. That is, one block is the erasure unit.

Word lines WL0-WL63 extend in the WL direction, and each of them is connected to memory cell transistors MT belonging to the same row. A select gate line SGD extends in the WL direction, and is connected to all the select transistors S2 in the block. A select gate line SGS extends in the WL direction, and is connected to all the select transistors S1 in the block.

Memory cell transistors MT connected to the same word line WL forms a unit referred to as a page. Data is read and written per page. For a multi-level memory cells each of which can store more than one bits, more than one pages are assigned to one word line.

A memory cell MT is provided at each intersection of the bit lines BL and the word lines WL. The memory cell MT is provided on a well formed in the semiconductor substrate. The well is connected to a voltage generation circuit 12, and receives a predetermined voltage from the voltage generation circuit 12. The memory cell MT includes a tunnel insulating film (not shown) stacked on the well, a floating electrode as a charge accumulation layer (or, floating gate electrode) FG, an inter-gate insulation film (not shown), a control electrode (or, control gate electrode) CG (word line WL), and source/drain regions SD. The source/drains, which serve as a current path of the memory cell MT, is connected in series to the source/drain of the adjacent memory cell MT. The select transistors S1, S2 include a gate insulation film (not shown) stacked on the semiconductor substrate, gate electrodes SGS, SGD, and source/drain regions SD, respectively.

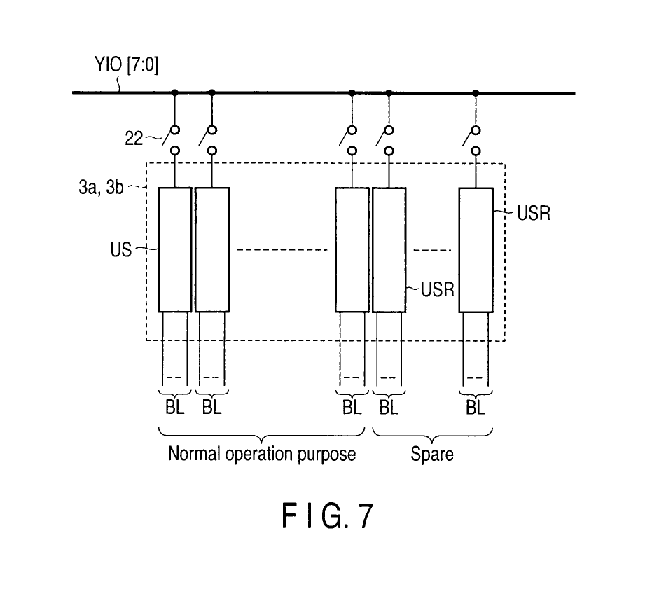

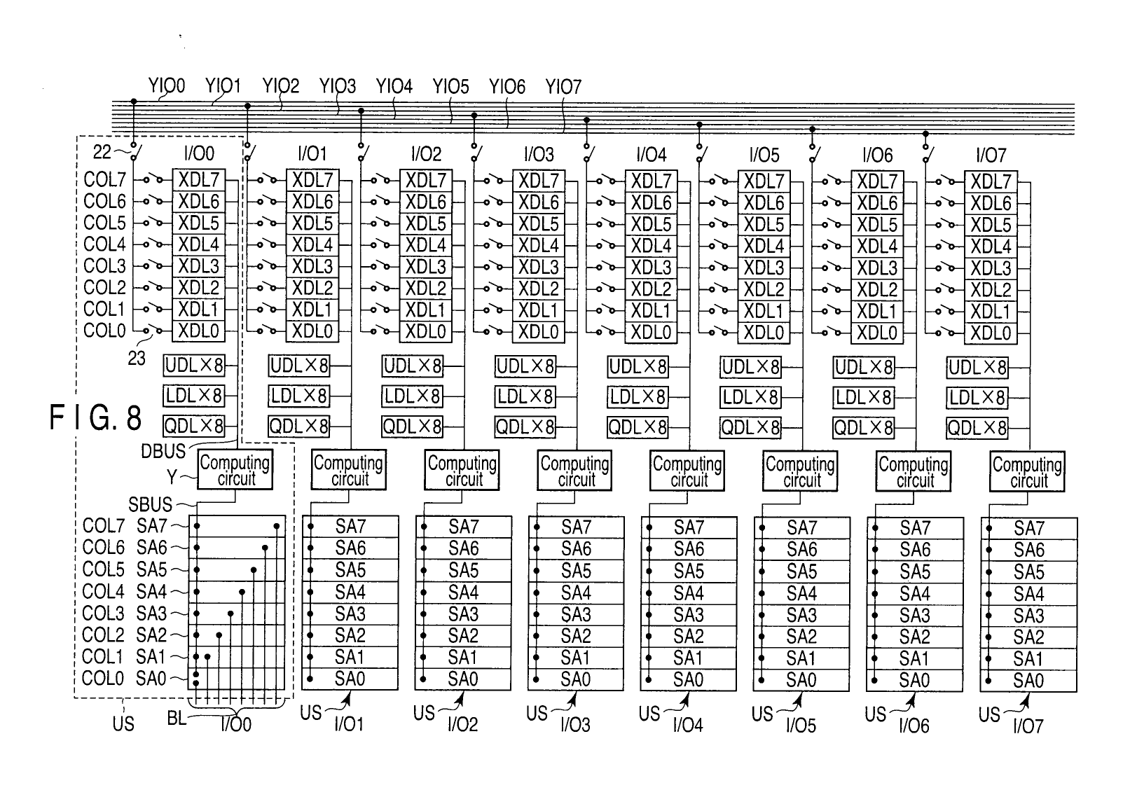

The sense amplifier circuit 3a and the data latches 3b will now be described with reference to FIGS. 7 and 8. The sense amplifier circuit 3a and the data latches 3b include a plurality of unit structures US. Each unit structure US includes sense amplifiers, data buses, data latches, a computing circuit, as will be described below. Each unit structure US is connected to eight bit lines BL, and is connected to a data bus YIO via a switch circuit 22. Components denoted by the reference numeral USR will be described below.

FIG. 8 is a block diagram illustrating unit structures US. FIG. 8 also illustrates the layout of the unit structure US, and the longitudinal and the lateral direction of FIG. 8 match the bit-line direction and the word-line direction, respectively, of FIG. 5. As shown in FIG. 8, one unit structure US corresponds to one of I/O0-I/O7. FIG. 8 illustrates eight unit structures US. The eight unit structures US have the same configuration, except that the different data lines (i.e., data buses YIO) are connected thereto, as will be described below.

Each unit structure US includes sense amplifiers SA0-SA7 arranged along the bit-line direction at the lower end (i.e., side closer to the memory array 2). Each of the sense amplifiers SA0-SA7 is connected to one bit line BL. The sense amplifiers SA0-SA7 are connected to one data bus SBUS common to one unit structure US. The data bus SBUS extends along the bit-line direction, and has a one-bit width.

The data bus SBUS is connected to one end of the computing circuit Y. The computing circuit Y is positioned on the upper side of the data bus SBUS. The other end of the computing circuit Y is connected to a set of data latches XDL-XDL7 via one common data bus DBUS. The data latches XDL0-XDL7 are arranged along the bit-line direction. The computing circuit Y connects the other end thereof to selected one of the data latches XDL0-XDL7. The computing circuit Y realizes an operation enabling more than one bits to be written into one memory cell. Since the computing circuit Y realizes connection between the computing circuit Y and selected one of the data latches XDL0-XDL7, only one data bus is needed between them in one unit structure US.

The unit structure US also includes eight data latches UDL, eight data latches LDL, and eight data latches QDL. The set of data latches UDL, the set of data latches LDL, and the set of data latches QDL are arranged along the bit-line direction, and are positioned between the computing circuit Y and the set of data latches XDL. The computing circuit Y connects the other end of the computing circuit Y to selected one of the eight data latches UDL, selected one of the eight data latches LDL, and selected one of the eight data latches QDL, via the data bus DBUS.

In one unit structure US, the data latches XDL0-XDL7 are connected to one common line via respective eight switch circuits 23. This common line is connected to one of the eight data lines YIO0-YIO7 forming the data bus YIO via the switch circuit 22. More specifically, the unit structures US0-US7 are connected to the data lines YIO0-YIO7, respectively. The unit structures US0-US7 correspond to the I/O0-I/O7, respectively.

The sense amplifiers SA0 of the unit structure US0-US7 amplify data for the I/O0-I/O7, respectively, of the column COL0. Similarly, the sense amplifiers SA1-SA7 amplify data of the columns COL1-COL7 for the I/O to which each of the sense amplifiers SA1-SA7 belongs.

Upon data reading, eight one-bit data items for the I/O0-I/O7 of the column COL0 are input to the sense amplifiers SA0 of the I/O0-I/O7. After that, the data items amplified by sense amplifiers SA0 of the I/O0-I/O7 are held by the data latches XDL0 of the I/O0-I/O7 via computing circuits Y each dedicated to one of the I/O-I/O7, respectively. The data items held by the data latches XDL0 of the I/O0-I/O7 is supplied to the data lines YIO0-YIO7, respectively. Thus, data items for the I/O0-I/O7 of the column COL0 are collectively transferred to the data bus YIO.

Next, data items of the column COL1 are transferred in a similar way. That is, eight one-bit data items for the I/O0-I/O7 of the column COL1 is input to the sense amplifiers SA1 of the I/O0-I/O7. After that, the data items amplified by sense amplifiers SA1 of the I/O0-I/O7 are held by the data latches XDL1 of the I/O-I/O7 via the computing circuits Y each dedicated to one of the I/O0-I/O7, respectively. The data items held by the data latches XDL1 of the I/O-I/O7 are supplied to the data lines YIO0-YIO7, respectively. Thus, data items for the I/O0-I/O7 of the column COL1 are collectively transferred to the data bus YIO. Sets of eight data items of the columns COL2-COL7 are sequentially transferred to the data bus YIO in a similar way. The unit by which the procedure is collectively performed differs between FIG. 1 and FIG. 8; however the time taken to transfer data items of eight columns with eight-bit data items per column to the data bus YIO of FIG. 8 and the of FIG. 1 remains the same.

Thus, operations are sequentially performed by the unit of a set of sense amplifiers that is arranged in a row direction (or, word-line direction) and belongs to one unit structure US. Accordingly, the sense amplifiers SA0-SA7 function for the columns COL0-COL7, respectively. The eight unit structures US shown in FIG. 8 form an operation unit, and such operation units are repeatedly arranged. Hereinafter, eight consecutive unit structures will be referred to as an operation unit structure. The other operation unit structures following that shown in FIG. 8 correspond to the columns COL8-COL15, and the same applies to the columns that follow.

In the present embodiment, operations are performed by the unit of a set of sense amplifiers that is arranged in a row direction (or, word-line direction) and belongs to one unit structure US. On the other hand, in the configuration of FIG. 1, operations are performed by the unit of a set of sense amplifiers that is arranged in a column direction (or, bit-line direction) and belongs to one column. One set of sense amplifiers that operates simultaneously differs in the two cases; however the time taken to transfer data items of eight columns remains the same.

As described above, eight unit structures US cooperatively operate as one operation unit, and transfer data items of eight columns to the data bus YIO. With this configuration, replacement can be performed by a unit different from that of FIG. 1. In the case of FIG. 1, in order to recover any of the components (computing circuits, data buses, data latches) included in FIG. 1 except for bit lines and sense amplifiers, all the components included in FIG. 1 need to be replaced. On the other hand, the configuration of the semiconductor memory device of the first embodiment uses one unit structure US as the replacement unit. This is because interconnection is closed within one unit structure US, and the components within one unit structure US are not used by another unit structure US, as is clear from FIG. 8.

The redundancy system in the semiconductor memory device of the first embodiment will now be described in detail with reference to FIGS. 7 and 9-11. As shown in FIG. 7, the bit-line control circuit 3 further includes unit structures USR in addition to unit structures US. The unit structures US are used for normal operation, and the unit structures USR are spares for replacement. Each spare unit structure USR has a configuration same as that of the unit structure US. Each spare unit structure USR is also connected to one of the data lines forming the data bus YIO.

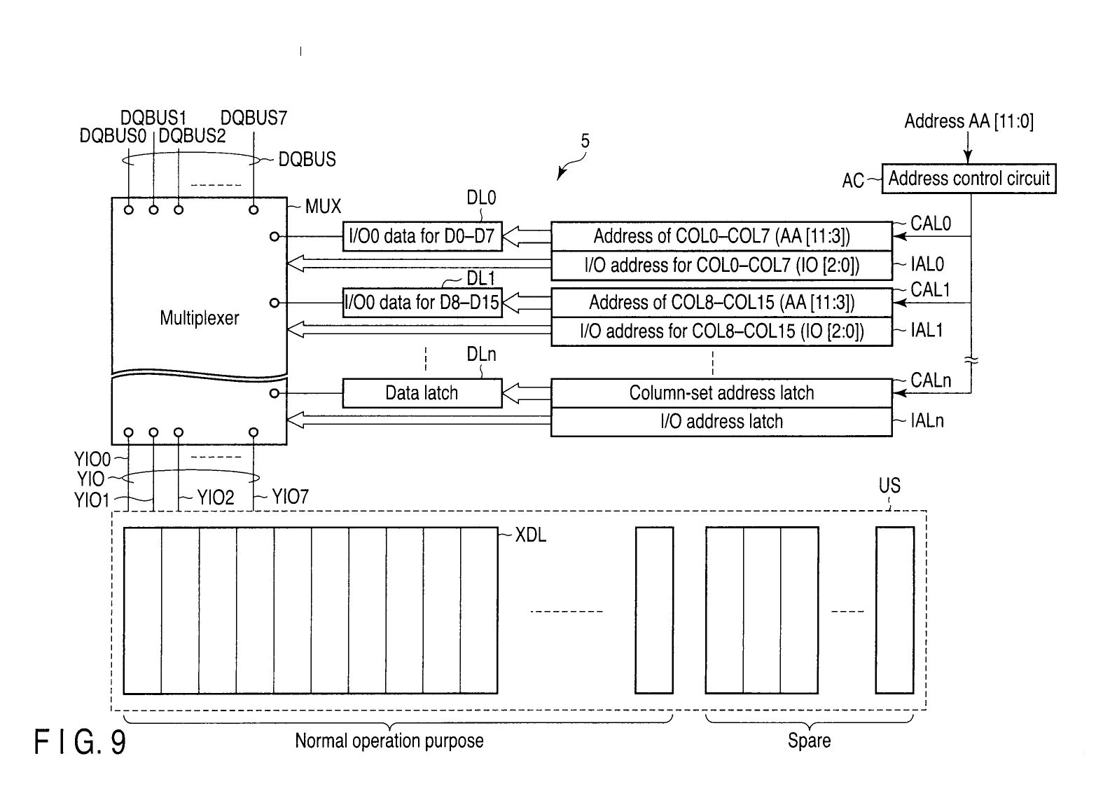

FIG. 9 is a block diagram illustrating a circuit relating to the redundancy circuit 5. As shown in FIG. 9, the redundancy circuit 5 includes an address control circuit AC, a multiplexer MUX, n (n being a natural number) address latches CAL0-CALn, n I/O address latches IAL0-IALn, and n data latches DL0-DLn.

The data bus DQBUS is connected to the address control circuit AC. The address control circuit AC retrieves the address signal AA on the data bus DQBUS. The address control circuit AC is connected to the column-set address latches CAL0-CALn. Each of the columns-set address latches CAL0-CALn holds an address specifying one operation unit structure, which is formed of eight consecutive unit structures US as illustrated in FIG. 8 and includes a replaced unit structure US. One column-set address can be specified from the address AA. That is, the address AA specifies the unit structure connected to the bit line connected to the memory cell specified by that address. The operation unit structure including that unit structure can also be specified from upper bits of that address. Thus, one column-set address is formed of only some of the bits that can specify the operation unit structure. For example, assume that the address AA specifying the memory cell has 12 bits, 9 upper bits of the 12-bit address are held in the column-set address latches CAL0-CALn (AA [11:3]). The following descriptions will assume this example.

The I/O address latches IAL0-IALn correspond to the column-set address latches CAL0-CALn, respectively. The I/O address latches IAL0-IALn hold a portion of the address AA, which is a portion of the address AA without the column-set address portion. The I/O address held by the I/O address latches IAL0-IALn are designed to specify one I/O in eight columns (which form an operation unit structure), and has 3 bits in this context.

The data latches DL0-DLn correspond to the column-set address latches CAL0-CALn, respectively. The data latches DL0-DLn are designed to hold the eight-bit data handled by one of the eight unit structures US specified by the column-set address held by the column-set address latches CAL0-CALn, respectively. As a specific example, when one unit structure US for the I/O0 of the columns COL0-COL7 has been replaced, the data latch DL0 holds eight-bit data handled by the I/O0 of the columns COL0-COL7.

The address control circuit AC compares the column-set-specifying portion (AA [11:3]) of the address AA that specifies the access target with the column-set addresses in the column-set address latches CAL0-CALn. If agreement occurs, one of the data latches DL0-DLn that corresponds to one of the column-set address latches CAL0-CALn holding the matched column-set address outputs the data held therein.

The multiplexer MUX selectively connects a data bus DQBUS, a data bus YIO, and data latches DL0-DLn. Normally, the multiplexer MUX connects the data lines DQBUS0-DQBUS7 forming the data bus DQBUS to the data lines YIO0-YIO7 forming the data bus YIO, respectively. On the other hand, when the column-set-specifying portion of the access-target-specifying address agrees with a column-set address in the column-set address latches CAL0-CALn, one of the data latches DL0-DLn corresponding to one of the column-set address latches CAL0-CALn holding the matched column-set address is connected to the data bus DQBUS or the YIO. Further, the multiplexer MUX connects enabled one of the data latches DL0-DLn and selected one of the data lines forming the data bus DQBUS or the data bus YIO, according to the I/O address in the corresponding one of I/O address latches IAL0-IALn. Accordingly, the multiplexer MUX is configured to connect the data latch DL0 to any of the data lines DQBUS0-DQBUS7, and any of the data lines YIO0-YIO7. Similarly, the multiplexer MUX is configured to connect any of the data latches DL1-DLn to any of the data lines DQBUS0-DQBUS7 and any of the data lines YIO0-YIO7.

Note that FIG. 9 illustrates only the data latches XDL of the unit structure US as a representative, and FIG. 9 illustrates each data latch XDL as corresponding to one unit structure US, that is, holding eight-bit data.

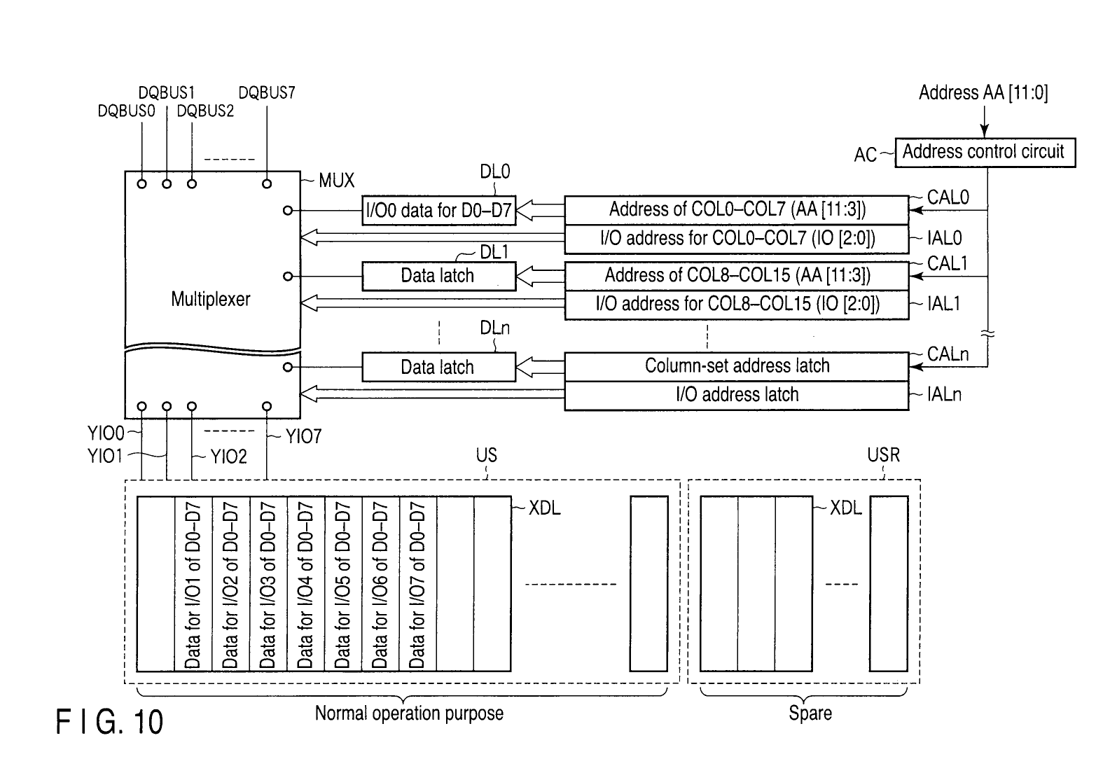

The operations of the redundancy circuit 5 and the related portions in FIG. 9 will now be described with reference to FIGS. 10-12. The following descriptions assume that the unit structure US for the I/O0 data of the operation unit structure for the columns COL0-COL7 and the unit structure US for the I/O0 data of the operation unit structure US for the columns COL8-COL15 have been replaced with spare unit structure USR. Accordingly, the column-set address latch CAL0 holds an address specifying the operation unit structure corresponding to the columns COL0-COL7, and the corresponding I/O address latch IAL0 holds an address specifying the I/O0. Similarly, the column-set address latch CAL1 holds an address specifying the operation unit structure corresponding to the columns COL8-COL15, and the corresponding I/O address IAL1 holds an address specifying the I/O0.

FIGS. 10-12 sequentially illustrate the operations when data is externally input to the semiconductor memory device 1. Normally, the multiplexer MUX connects the data line DQBUS0-DQBUS7 and the data lines YIO0-YIO7, respectively. As shown in FIG. 10, data items D0-D7 are sequentially supplied to the multiplexer MUX. The data item D0 consists of eight bits for I/O0-I/O7 of the column COL0. Similarly, each of the data items D1-D7 consists of eight bits for the I/O0-I/O7 of the operation unit structure corresponding to the columns COL1-COL7, respectively.

In parallel with supply of the data items D0-D7 to the redundancy circuit 5, the addresses of the memory cells that are to hold the data items D0-D7 are supplied to the address control circuit AC. The address control circuit AC detects that the column-set address of the data items D0-D7 matches the column-set address in the column-set address latch CAL0. With this detection, the address control circuit AC causes the multiplexer MUX to output an I/O address in the I/O address latch IAL0. Upon receipt of this I/O address, the multiplexer MUX connects the data line DQBUS0 for the I/O0 in the data bus DQBUS to the data latch DL0. The data item D0 is then supplied to the redundancy circuit 5. Then, the segment of the data item D0 for the I/O0 is held in the data latch DL0, and the remaining segment of the data item D0 for the remaining I/O1-I/O7 is held in each data latch XDL0 in the unit structures US for the I/O1-I/O7 in the operation unit structure corresponding to the columns COL0-COL7.

The redundancy circuit 5 then receives data item D1. Then, as in the case of the data item D0, the segment of the data item D1 for the I/O0 is held in the data latch DL0, and the remaining segment of the data item D1 for I/O1-I/O7 is held in each data latch XDL1 in the unit structures US for the I/O1-I/O7 in the operation unit structure corresponding to the columns COL0-COL7, respectively.

Similarly, the redundancy circuit 5 sequentially receives data items D2-D7. Then, segments of the data items D2-D7 for the I/O0 are sequentially held in the data latch DL0, and segments of the data items D2-D7 for the I/O1-I/O7 are sequentially held in the data latches XDL2-XDL7 in the unit structures US for the I/O1-I/O7 in the operation unit structure.

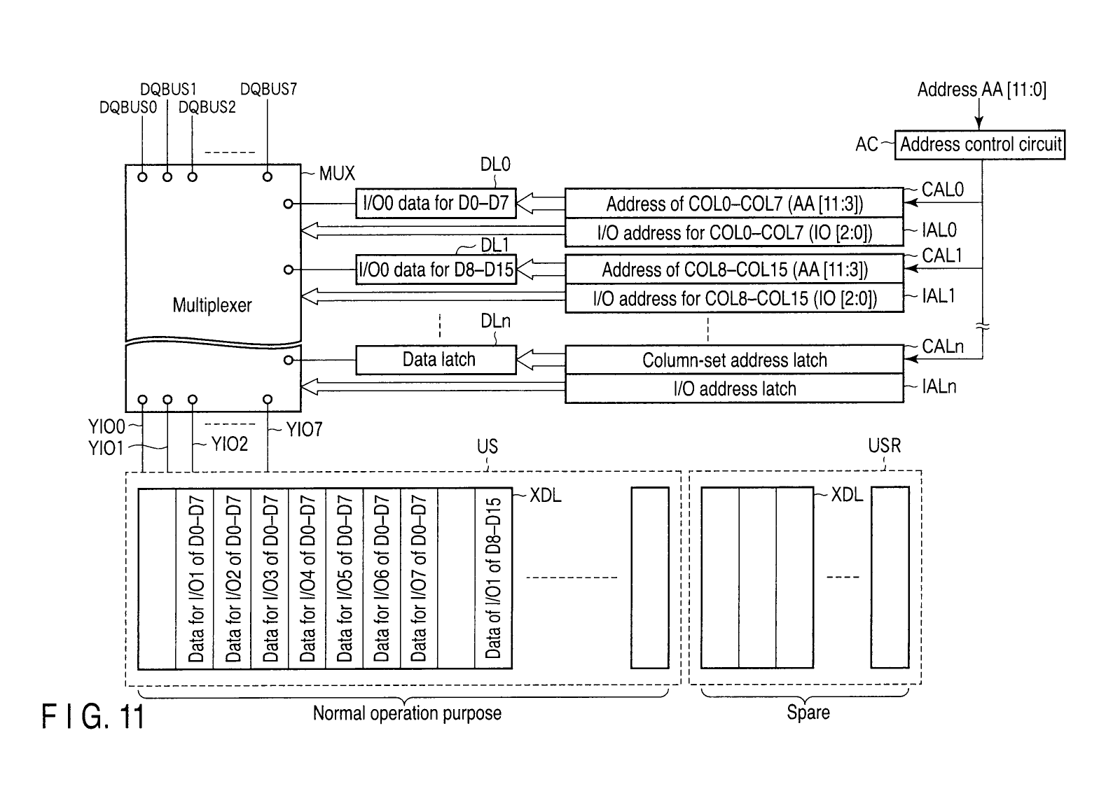

Next, as shown in FIG. 11, the data items D8-D15 are sequentially supplied to the multiplexer MUX. Each of the data items D8-D15 consists of eight bits for the I/O0-I/O7 of the operation unit structure corresponding to the columns COL8-COL15, respectively. As described with reference to FIG. 10, the address control circuit AC detects that the column-set address of the data items D8-D15 agrees with the column-set address in the column-set address latch CAL1, and then causes the multiplexer MUX to output an I/O address in the I/O address latch IAL1 Upon receipt of this I/O address, the multiplexer MUX connects the data line DQBUS0 for the I/O0 in the data bus DQBUS to the data latch DL1. Thereby, the data segments of data items D8-D15 for the I/O0 are sequentially held in the data latch DL1, and the remaining segments of the data items D8-D15 for the I/O1-I/O7 are sequentially held in the data latches XDL0-XDL7, respectively, of the unit structures US for the I/O1-I/O7 in the operation unit structure corresponding to the columns COL8-COL15.

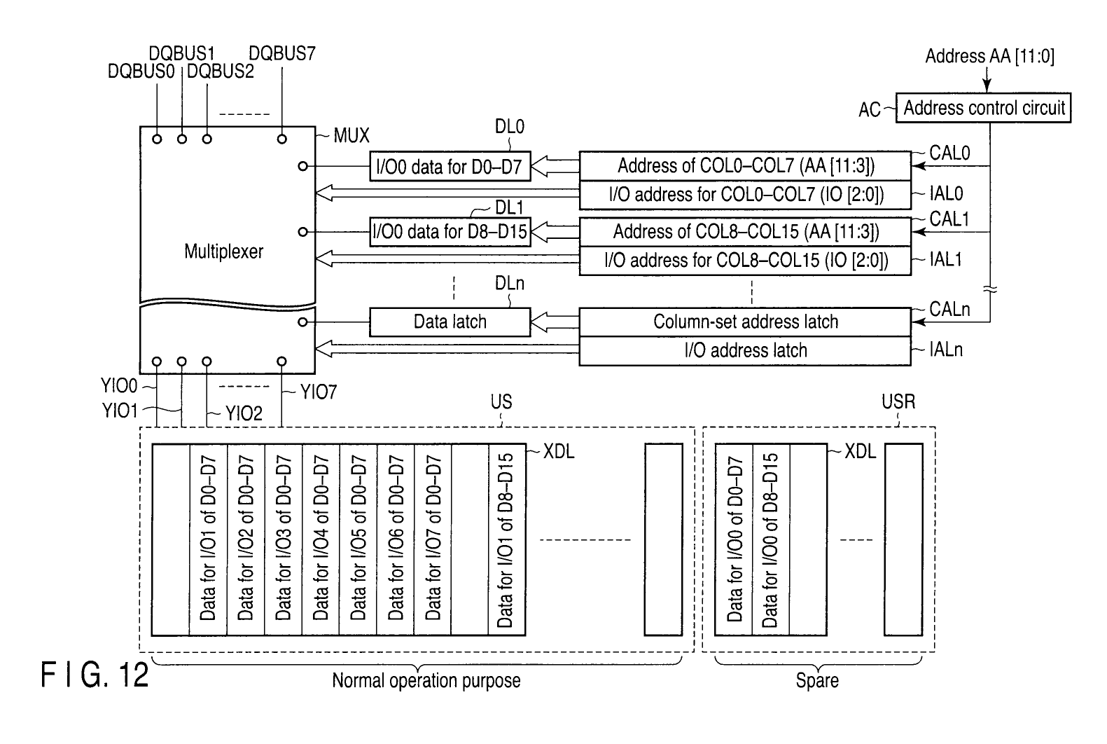

FIG. 12 illustrates the step when the program command is supplied to the semiconductor memory device 1, following FIG. 11. As shown in FIG. 12, each data segment for the I/O0 of the columns COL0 and COL8 previously held in the respective data latches DL0 and DL1 is held in the data latch XDL0 of the unit structure USR0 and the data latch XDL0 of another unit structure USR1. Similarly, the each data segment for the I/O0 of each of the columns COL1 and COL9 is held in the data latch XDL1 of the unit structure USR0 and the data latch XDL1 of the unit structure USR1. Similarly, the data segments for the I/O0 of the columns COL2-COL7 and the columns COL10-15 are sequentially held in the data latch XDL2-XDL7 of the unit structure USR0 and the data latches XDL2-XDL7 of the unit structure USR1, respectively. After that, data held in the data latches XDL0-XDL7 of each of the unit structures US, USR0, USR1 is written to the memory cell array via the computing circuit Y and the sense amplifiers SA0-SA7.

Data reading is performed in the same way as data writing. The data read from the memory cell array reaches the data latches XDL0-XDL7 via the sense amplifiers SA0-SA7 and the computing circuit Y. The data to be handled by the unit structure USR replacing the defective unit structure US is processed by the replaced unit structure USR and held therein. The address control circuit AC compares the column-set address of the memory cells to be read with the column-set address in the column-set address latches CAL0-CALn. When agreement occurs, the control by the corresponding I/O address latches IAL0-IALn and the multiplexer MUX sequentially transfers data for the corresponding I/O to one of the corresponding data latches DL0-DLn from the data latches XDL0-XDL7. The data for I/Os not specified by the I/O address latches IAL0-IALn is transferred to the data bus DQBUS via the multiplexer MUX from the data latches XDL. After that, the data held in a corresponding one of the data latches DL0-DLn is transferred to the data bus DQBUS via the multiplexer MUX.

As described above, according to the semiconductor memory device of the first embodiment, one computing circuit Y and a set of data latches XDL0-XDL7 arranged in a bit-line direction are used only by a set of sense amplifiers SA0-SA7 arranged in a bit-line direction. Accordingly, the one computing circuit Y, the set of data latches XDL, and the set of sense amplifiers SA form one separate unit structure US, and the unit structure US corresponds to one I/O of eight columns. Therefore, the unit of replacement can be the unit structure US even with the configuration that operates by the unit of eight columns. Thereby, a semiconductor memory device having a higher replacement efficiency (for example, than the configuration of FIG. 1) can be provided.

Further, according to the unit structure US of the present embodiment, connection from a set of sense amplifiers SA to the computing circuit Y is realized by only one data bus SBUS. Thereby, the pitch of the data buses SBUS are larger, than, for example, FIG. 1, which alleviates restrictions imposed on interconnects design.

### Second Embodiment

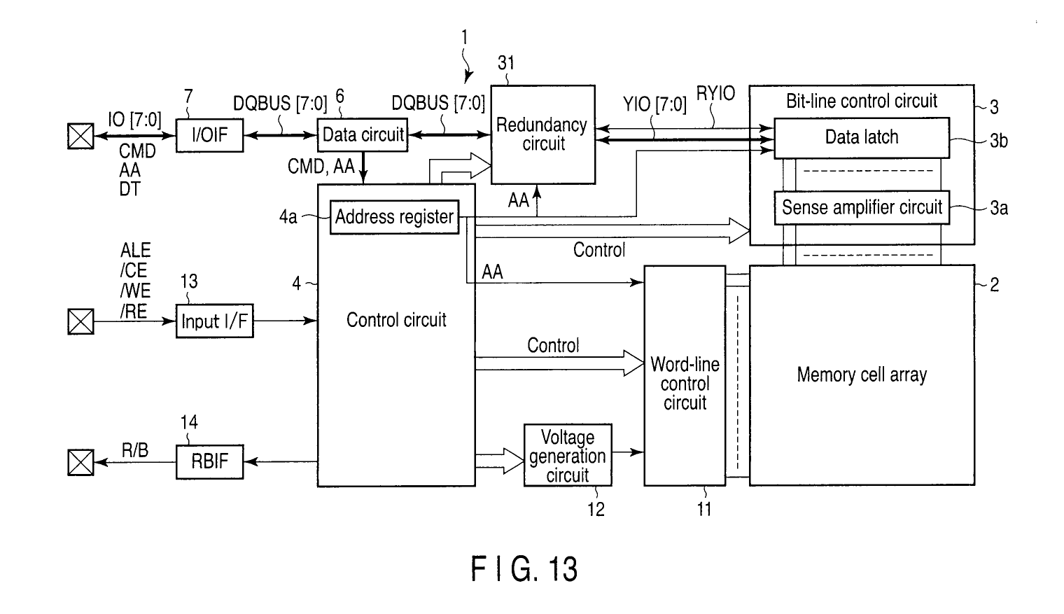

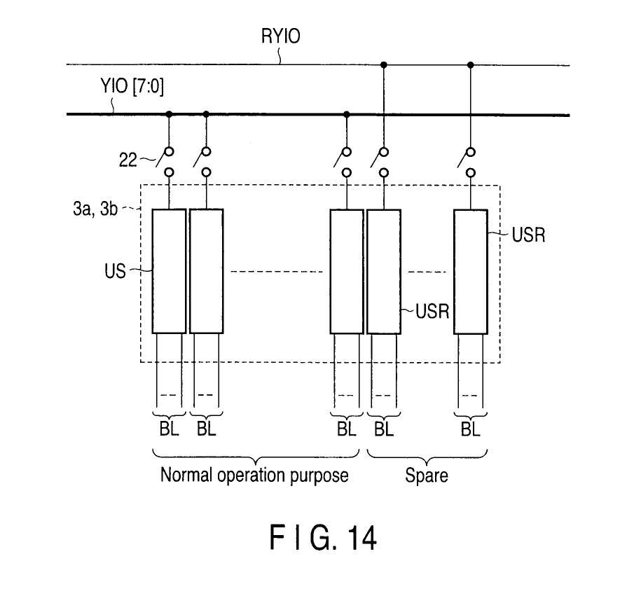

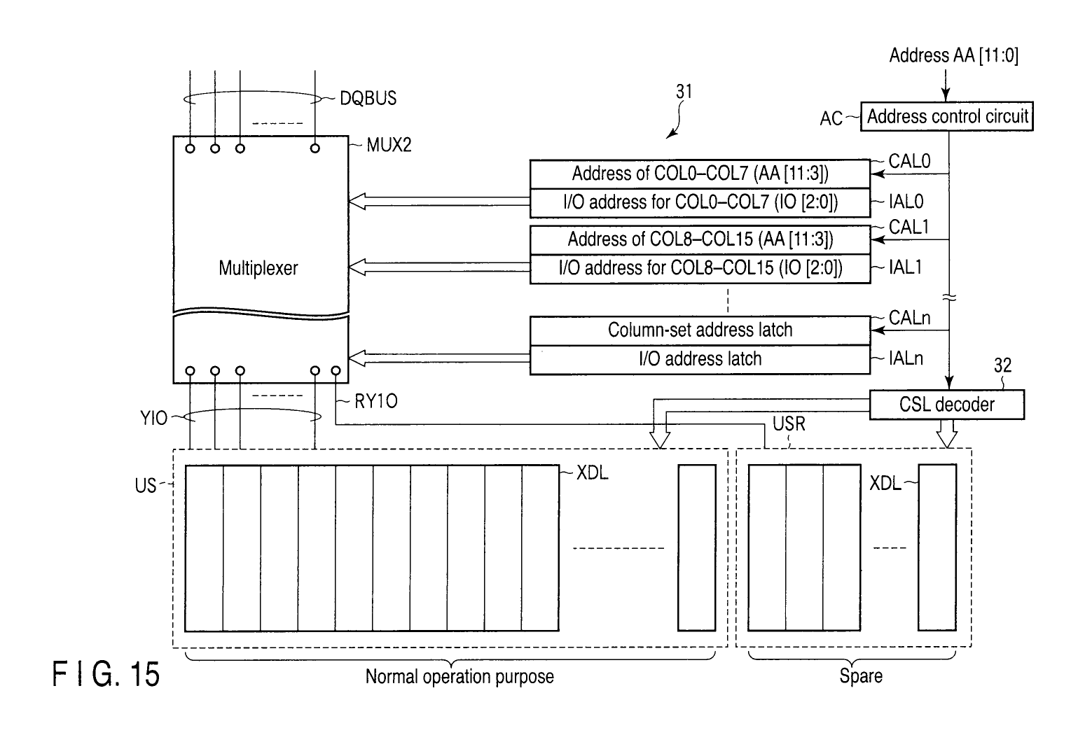

FIG. 13 is a block diagram schematically illustrating a semiconductor memory device according to the second embodiment. As shown in FIG. 13, the semiconductor memory device of the second embodiment includes a redundancy circuit 31 instead of the redundancy circuit 5. The redundancy circuit 31 is connected to data latches 3b via a data bus RYIO. A more specific configuration is shown in FIG. 14. A unit structure US for normal operation is the same as that of the first embodiment. A spare unit structure USR is connected to the data bus RYIO of one-bit width via a switch 22. The configuration of the second embodiment other than that described here is the same as that of the first embodiment.

FIG. 15 is a block diagram illustrating a circuit relating to a redundancy circuit 31. As shown in FIG. 15, the redundancy circuit 31 does not include data latches DL0-DLn included in the redundancy circuit 5. A multiplexer MUX2 connects data lines DQBUS0-DQBUS7 forming a data bus DQBUS and data lines YIO0-YIO7 forming a data bus YIO. The multiplexer MUX2 also connects selected one of the data lines DQBUS0-DQBUS7 to the data bus RYIO. Each of the column-set address latches CAL0-CALn forms a pair with corresponding one of the I/O address latches IAL0-IALn.

The redundancy circuit 31 further includes a CSL decoder 32. An address to be accessed is supplied from the address control circuit AC to the CSL decoder 32. The CSL decoder 32 decodes the supplied address and controls the switches 22 of FIG. 14.

The operation of the redundancy circuit 31 will be described in a context with a unit structure US corresponding to the access target replaced. As in the case of the first embodiment, the address control circuit AC compares the column-set address extracted from the supplied address with the column-set addresses in the column-set address latches CAL0-CALn. When agreement does not occur, the multiplexer MUX2 connects the data lines DQBUS0-DQBUS7 of the data bus DQBUS to the data lines YIO0-YIO7 of the data bus YIO.

When agreement occurs, one of the column-set address latches CAL0-CALn whose column-set address agrees causes the multiplexer MUX2 to output an I/O address in a corresponding one of the I/O address latches IAL0-IAL. Upon receipt of this I/O address, the multiplexer MUX2 connects a data line of the data bus DQBUS (such as the DQBUS0) that carries data of an I/O specified by the I/O address (such as I/O0) to the data bus RYIO. Thereby, data transfer path is formed between the data bus DQBUS and the unit structure USR (more specifically, data latches XDL).

The descriptions given above has assumed that only one data bus RYIO is provided between the multiplexer MUX2 and the spare unit structure USR. This poses a restriction that only one of eight unit structures cooperating for a set of eight columns can be replaced. Increased number of data buses RYIO can result in more possible unit structures replaced among the eight columns.

As described above, according to the semiconductor memory device of the second embodiment one computing circuit Y and a set of data latches XDL are used only by a set of sense amplifiers SA as in the first embodiment, which produces advantages same as that of the first embodiment.

Further, the second embodiment provides a data bus RYIO that can be connected only to the spare unit structure USR. That is, a dedicated data bus RYIO for carrying data from/to the spare unit structure USR is provided. Accordingly, such data does not need to be latched in the redundancy circuit 31, and a data latch will be unnecessary. Further, since no data latches need to be connected to the data bus DQBUS and YIO, the configuration of the multiplexer MUX2 can be simplified.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
unit structures each comprising:
bit lines connected to memory cells;
sense amplifiers connected to respective bit lines adjacent to each other;
a first data line commonly connected to the sense amplifiers;
a computing circuit connected to the first data line;
a second data line connected to the computing circuit; and
data latches connected to the second data line, wherein
the unit structures are independent from one another,
at least one of the unit structures is a spare unit structure, and
one of the unit structures is configured to be replaceable with the spare unit structure.

2. The device according to claim 1, further comprising:
operation unit structures each comprising a subset of the unit structures;
third data lines that carry data to or from the unit structures included in one of operation unit structures;
fourth data lines electrically connected to input/output terminals of the semiconductor memory device;
a first latch that holds a first address specifying one of the operation unit structures to which a replaced unit structure that has been replaced with the spare unit structure belongs;
a second latch that holds a second address specifying the replaced unit structure among unit structures included in the specified operation unit structure;
a third latch that holds data supplied to or from the spare unit structure; and
a multiplexer that connects one of the third data lines specified by the second address or one of the fourth data lines specified by the second address to the third latch when a portion of an address of one memory cell to be accessed matches the first address.

3. The device according to claim 2, wherein
the multiplexer connects each of the third data lines to one of the fourth data lines that is associated in advance when the portion of an address of one memory cell to be accessed does not agree with the first address.

4. The device according to claim 1, further comprising:
operation unit structures each comprising a subset of unit structures;
third data lines that carry data to or from the unit structures included in one of operation unit structures;
fourth data lines electrically connected to input/output terminals of the semiconductor memory device;
a fifth data line that carries data to or from the spare unit structure;
a first latch that holds a first address specifying one of the operation unit structures to which a replaced unit structure that has been replaced with the spare unit structure belongs;
a second latch that holds a second address specifying the replaced unit structure among unit structures included in the specified operation unit structures; and
a multiplexer that connects one of the fourth data lines specified by the second address and the fifth data line when a portion of an address of one memory cell to be accessed matches the first address.

5. The device according to claim 4, wherein
the multiplexer connects each of the third data lines to one of the fourth data lines that is associated in advance when the portion of an address of one memory cell to be accessed does not agree with the first address.

6. The device according to claim 1, wherein
in each of the unit structures,
the sense amplifiers comprise first to n-th sense amplifiers (n being a natural number greater than 1),
the data latches comprise first to n-th data latches, and
the first to n-th data latches latch data to or from the first to nth sense amplifiers, respectively.

7. The device according to claim 6, further comprising:
operation unit structures each comprising a subset of the unit structures;
third data lines that carry data to or from the unit structures included in one of operation unit structures;
fourth data lines electrically connected to input/output terminals of the semiconductor memory device;
a first latch that holds a first address specifying one of the operation unit structures to which a replaced unit structure that has been replaced with the spare unit structure belongs;
a second latch that holds a second address specifying the replaced unit structure among unit structures included in the specified operation unit structure;
a third latch that holds data supplied to or from the spare unit structure; and
a multiplexer that connects one of the third data lines specified by the second address or one of the fourth data lines specified by the second address to the third latch when a portion of an address of one memory cell to be accessed matches the first address.

8. The device according to claim 7, wherein
the multiplexer connects each of the third data lines to one of the fourth data lines that is associated in advance when the portion of an address of one memory cell to be accessed does not agree with the first address.

9. The device according to claim 6, further comprising:
operation unit structures each comprising a subset of unit structures;
third data lines that carry data to or from the unit structures included in one of operation unit structures;
fourth data lines electrically connected to input/output terminals of the semiconductor memory device;
a fifth data line that carries data to or from the spare unit structure;
a first latch that holds a first address specifying one of the operation unit structures to which a replaced unit structure that has been replaced with the spare unit structure belongs;
a second latch that holds a second address specifying the replaced unit structure among unit structures included in the specified operation unit structures; and
a multiplexer that connects one of the fourth data lines specified by the second address and the fifth data line when a portion of an address of one memory cell to be accessed matches the first address.

10. The device according to claim 9, wherein
the multiplexer connects each of the third data lines to one of the fourth data lines that is associated in advance when the portion of an address of one memory cell to be accessed does not agree with the first address.

11. The device according to claim 6, further comprising third data lines, wherein
each of the unit structures is associated with one of the third data lines, and
each of the unit structures includes a switch that connects a selected one of the data latches of the unit structure to the associated one of the third data lines.

12. The device according to claim 11, wherein
the unit structures comprise operation unit structures each comprising a subset of unit structures of predetermined number, and
the predetermined number is equal to the number of the third data lines.

13. The device according to claim 12, further comprising:
fourth data lines electrically connected to input/output terminals of the semiconductor memory device;
a first latch that holds a first address specifying one of the operation unit structures to which a replaced unit structure that has been replaced with the spare unit structure belongs;
a second latch that holds a second address specifying the replaced unit structure among unit structures included in the specified operation unit structure;
a third latch that holds data supplied to or from the spare unit structure; and
a multiplexer that connects one of the third data lines specified by the second address or one of the fourth data lines specified by the second address to the third latch when a portion of an address of one memory cell to be accessed matches the first address.

14. The device according to claim 13, wherein
the first address comprises a predetermined number of upper bits of an address of one of the memory cells,
the second address comprises the remaining bits of the address of one of the memory cells without the upper bits and specifies one unit structure among one operation unit structure, and
each of the operation unit structures includes a subset of the unit structures associated with a subset of the memory cells having the same first address.

15. The device according to claim 14, wherein
the multiplexer connects each of the third data lines to one of the fourth data lines that is associated in advance when the portion of an address of one memory cell to be accessed does not agree with the first address.

16. The device according to claim 12, further comprising:
fourth data lines electrically connected to input/output terminals of the semiconductor memory device;
a fifth data line that carries data to or from the spare unit structure;
a first latch that holds a first address specifying one of the operation unit structures to which a replaced unit structure that has been replaced with the spare unit structure belongs;
a second latch that holds a second address specifying the replaced unit structure among unit structures included in the specified operation unit structures; and
a multiplexer that connects one of the fourth data lines specified by the second address and the fifth data line when a portion of an address of one memory cell to be accessed matches the first address.

17. The device according to claim 16, wherein
the first address comprises a predetermined number of upper bits of an address of one of the memory cells,
the second address comprises the remaining bits of the address of one of the memory cells without the upper bits and specifies one unit structure among one operation unit structure, and
each of the operation unit structures includes a subset of the unit structures associated with a subset of the memory cells having the same first address.

18. The device according to claim 17, wherein
the multiplexer connects each of the third data lines to one of the fourth data lines that is associated in advance when the portion of an address of one memory cell to be accessed does not agree with the first address.
